(19) United States
(12) Patent Application Publication
(10) Pub. No.: US 2009/0304196 A1
(43) Pub. Date: Dec. 10, 2009

(54) Wireless vocal microphone with built-in auto-chromatic pitch correction

(76) Inventor: Ronald Gordon Patton, Long Beach, CA (US)

Correspondence Address: Ronald G. Patton, 730 W. 4th Street, #308, Long Beach, CA, 90802, US

(21) Appl. No.: 12/457,213

(22) Filed: Jun. 3, 2009

Related U.S. Application Data
(60) Provisional application No. 61/059,589, filed on Jun. 6, 2008.

(51) Int. Cl. H03G 3/00; H03G 5/00; H04R 11/04

(52) U.S. Cl. 381/63; 381/103; 381/355

(57) ABSTRACT

A series of signal processing features incorporated into its design that is both functional and decorative, to enhance convenience and performance among vocalists. A hollow, cylinder shaped body is oriented lie a conventional microphone, featuring a cardioid pickup pattern and a dynamic diaphragm, as well as a three-pin/XLR connector, a grill, and an integral pop filter. A transmitter handling the conversion of the audio signal into a radio signal and broadcasts it through an antenna, is built into the handle of the microphone, resulting in a wireless microphone that is slightly larger than a standard wired microphone. The microphone also has a shock-absorption system that reduces noise while the microphone is being handled buy the vocalist during a performance.

This Application is based upon a Provisional Patent, Application No. 61/059,589 filed by Claimant on Jun. 6, 2008.

### FIELD OF THE INVENTION

The present invention relates to a handheld, wireless receiving/transmitting vocal microphone and, more particularly, to a high quality audio wireless vocal microphone ensuring reliable and specific auto-chromatic pitch correction in real time without interruption and/or dependence on external signal processing equipment.

### BACKGROUND OF THE INVENTION

Ever since vocal microphones were invented (e.g., wireless and non-wireless), vocalists, both professional and amateurs using them, always were concerned with singing on pitch during live and even in-studio performances.

Although there are many external mutlt-effects processors and various types of signal processing gear available on the market, the vocalist still needed to put all of this gear together before each performance in order to insure that the vocalist sounded more in tune with the backup musicians, which in turn would improve the overall quality of that performance.

A wide variety of wireless microphones have been recently proposed. However, none of these have not considered the combined use of wireless microphones with built in components comprising of, but not limited to auto-chromatic pitch correction, compression, effects/reverb, sibilance control and equalization, incorporated directly into its design.

Unfortunately, since all of these mutlt-effects processors and various types of signal processing gear were external, they had to be connected directly into other equipment, such as a sound mixing board, which might be located off stage and needed to be operated by a sound or audio technician. This add to the performance cost since all of this additional equipment needs to be transported to and from a venue when performing, not to mention the amount of time required to set-up and break-drown the equipment before and after each performance.

### SUMMARY OF THE INVENTION

In accordance with the present invention, there is provided a series of signal processing features incorporated into its design that is both functional and decorative, to enhance convenience and performance among vocalists. A hollow, cylinder shaped body is oriented like a conventional microphone, featuring a cardioid pickup pattern and a dynamic diaphragm, as well as a three-pin/XLR connector, a grill, and an integral pop filter. A foam windscreen would also be included, as would a 6-inch, clip on pop filter to the upper part or top of the microphone. The microphone also has a shock-absorption system that reduces noise while the microphone is being handled buy the vocalist during a performance.

It would be advantageous to provide a wireless vocal microphone having a container for audio signal processing features, including but not limited to pitch correction, compression, effects/reverb, sibilance control and equalization, incorporated directly into its design.

It would also be advantageous to provide a wireless vocal microphone having a series of four knobs or dials on the exterior of the microphone's housing for controlling the effects and or signal processing features.

It would also be advantageous to provide a wireless vocal microphone having an easily accessible on/off switch.

It would also be advantageous to provide a wireless vocal microphone having a pull out compartment near the base of the microphone's body, wherein 2 size AA Alkaline batteries may be inserted into said compartment to operate the microphone's built-in transmitter. These two batteries should provide about 6 to 8 hours operating time.

It would also be advantageous to provide an ac adapter for recharging when not in use.

It would further be advantageous to provide a wireless vocal microphone having a USB connector and cable, which would allow for connection to a home MAC or PC for computer-based recording.

The above summary of the invention is not intended to represent each embodiment of every aspect of the present invention.

### BRIEF DESCRIPTION OF THE DRAWINGS

A complete understanding of the present invention may be obtained by reference to the accompanying drawings, when considered in conjunction with the subsequent, detailed description, in which:

For purposes of clarity and brevity, like elements and components will bear the same designations and numbering throughout the Figures.

### DESCRIPTION OF THE PREFERRED EMBODIMENT

Before explaining at least one embodiment of the invention in detail, it is to be understood that the invention is not limited in its application to the details of construction and the arrangement of the components set forth in the following description or illustrated in the drawing(s). The invention is capable of other embodiments or of being practiced or carried out in various ways. Also, it is to be understood that the phraseology and terminology employed herein is for the purposes of description and should not be regarded as limiting.

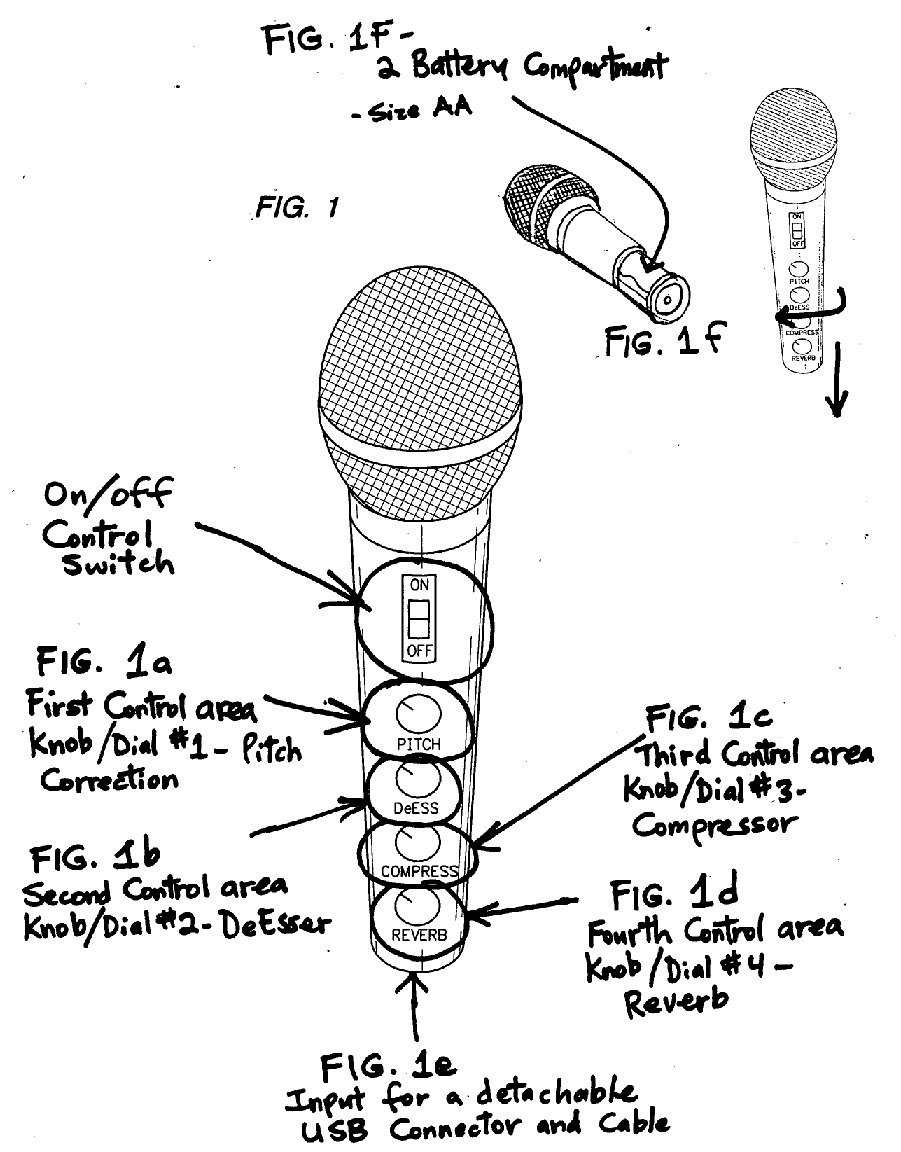

Referring to FIG. 1, FIG. 1a, FIG. 1b, FIG. 1c and FIG. d, a modified handheld wireless microphone according to the present invention is generally indicated at 1. The modified handheld wireless microphone 1 consists of a central section 2 having, located on the exterior of the present invention's housing, one on/off control switch, a series of four knobs or dials, each one 1/16″ in diameter, arranged in a vertical column, which the order (from top to bottom) and function of these knobs or dials, located beneath the on/off control switch, are as follows:

A. Knob/Dial #1—Pitch (FIG. 1a)—this automatically corrects or tune pitches that are slightly sharp or flat in real time.

B. Knob/Dial #2—DeEsser/high frequency filter (FIG. 1b)—this aids in real-time reduction of excess sibilance (“ess” and “shh” sounds) from vocal tracks during a live performance or recording session.

C. Knob/Dial #3—Compressor (FIG. 1c)—an automatic volume control that reduces the gain (level) of an audio signal (i.e., the performing vocalist) if its amplitude exceeds a certain threshold. This feature can be utilized on the vocal in order to make it stand out from the surrounding instruments and to add to the clarity of the vocal performance. Additionally, this feature can be used to reduce sibilance (‘ess’ sounds) in vocals by feeding the compressor with an EQ set to the relevant frequencies, so that only those frequencies of the vocal activate the compressor.

D. Knob/Dial #4—Reverb (FIG. 1d)—a built-in digital signal processor (DSP) using various signal processing algorithms in order to create the reverb effect.

In FIG. 1e, located at the bottom of the present invention, is an input for a detachable USB connector and cable, providing the option for connection to a home MAC or PC for computer-based recording. In addition, this would permit connection to external signal processing equipment, as well as karaoke machines in the event that is the preference of the vocal performer.

While the preferred embodiment shows one on/off control switch, a series of knob/dials in the central section 2, any order and/or positioning of these knobs/dials can be utilized or interchanged with one another. (i.e. knob/dial #1 could be positioned in the current position of knob/dial #4, as the drawing now shows and vice versa).

FIG. 1f of the preferred embodiment shows a pull out/slide out compartment located near the bottom of the invention, houses 2 size AA Alkaline batteries which provides 6 to 8 hours operation time of the invention in place of an optional ac power adapter.

Since other modifications and changes varied to fit particular operating requirements and environments will be apparent to those skilled in the art, the invention is not considered limited to the example chosen for purposes of disclosure, and covers all changes and modifications which do not constitute departures from the true spirit and scope of this invention.

Having thus described the invention, what is desired to be protected by Letters Patent is presented in the subsequently appended claims.

What is claimed is:

1. A modified handheld wireless vocal microphone, comprising:
A modified handheld wireless vocal microphone independent of the need for connection to any external signal processing equipment;
a central section, having an on/off control switch, a series of knobs or dials in direct vertical order of each other, for providing an area of control, connected to said modified handheld wireless microphone.
a first control area, for providing a means of automatically corrects or tune pitches of a vocalist that are slightly sharp or flat during a live performance or recording session in real time or recording session without connection to external signal processing equipment designated for such means, juxtaposed to said central area;
a second control area, for providing means for built-in/internal digital signal processor (DSP) using various signal processing algorithms in order to create the reverb effect and to control of the amount of reverb added to or removed from a vocalist during a live performance or recording session in real time or recording session without connection to external signal processing equipment designated for such means, juxtaposed to said central area;
a third control area, for built-in/internal reduction of excess sibilance (“ess” and “shh” sounds) from a vocalist during a live performance or recording session in real time without connection to external signal processing equipment, juxtaposed to said central area;
a fourth control area, for built in/internal automatic volume control that reduces the gain (level) of a vocalist during a live performance or recording session if the amplitude of the vocal signal exceeds a certain threshold in real time without connection to external signal processing equipment designated for such means, juxtaposed to said central area.

2. The modified wireless vocal microphone in accordance with claim 1, wherein said central section has located on the exterior housing of said modified handheld wireless vocal microphone, a series of light knobs or dials, each vertically positioned from the next, and each one 1/16″ in diameter.

3. The modified handheld wireless vocal microphone, in accordance with claim 1, wherein said first control area comprising: with built-in auto-chromatic pitch correction for vocal pitch correction, in accordance with claim 1, wherein said means comprises: a central section, having a series of four knobs or dials in vertical order of each other, on the exterior of the microphone's housing.

4. The modified handheld wireless vocal microphone, in accordance with claim 1, wherein said second control area comprising: means for built-in/internal digital signal processor (DSP) using various signal processing algorithms in order to create the reverb effect and to control of the amount of reverb added to or removed from a vocalist during a live performance or recording session in real time or recording session without connection to external signal processing equipment designated for such means, wherein said means comprises: a central section, having a series of four knobs or dials in vertical order of each other, on the exterior of the microphone's housing.

5. The modified handheld wireless vocal microphone, in accordance with claim 1, wherein said third control area comprising: built-in/internal reduction of excess sibilance (“ess” and “shh” sounds) from a vocalist during a live performance or recording session in real time without connection to external signal processing equipment, wherein said means comprises: a central section, having a series of four knobs or dials in vertical order of each other, on the exterior of the microphone's housing.

6. The modified handheld wireless vocal microphone, in accordance with claim 1, wherein said fourth control area comprising: built in/internal automatic volume control that reduces the gain (level) of a vocalist during a live performance or recording session if the amplitude of the vocal signal exceeds a certain threshold in real time without connection to external signal processing equipment designated for such means, wherein said means comprises: a central section, having a series of four knobs or dials in vertical order of each other, on the exterior of the microphone's housing.

7. The modified handheld wireless vocal microphone, in accordance with claim 1, wherein beneath said fourth control area comprising: built-in input of a detachable USB connector and cable, which would allow for connection, juxtaposed to said central area, within the interior of the microphone's housing.

8. The modified handheld wireless vocal microphone, in accordance with claim 1, wherein above said fourth control area comprising: built-in on/off control switch, which is inclusive of: a central section, having a series of four knobs or dials in vertical order of each other, on the exterior of the microphone's housing.

9. The modified handheld wireless vocal microphone, in accordance with claim 1, wherein beneath said fourth control area comprising: built-in pull-out compartment housing 2 size AA Alkaline batteries as an alternative power source to an optional ac adapter, which would allow for powering the invention's built-in transmitter, juxtaposed to said central area, within the interior of the microphone's housing. Access to said batteries' compartment is made by turning the invention's outer body in a counter-clockwise direction or motion.
